(19) United States
(12) Patent Application Publication
(10) Pub. No.: US 2025/0183045 A1
(43) Pub. Date: Jun. 5, 2025

(54) METHOD FOR FABRICATION OF SEMICONDUCTOR STRUCTURES AND APPARATUS FOR FABRICATION OF THE SAME

(71) Applicant: National Yang Ming Chiao Tung University, Hsinchu City (TW)

(72) Inventor: Seiji Samukawa, Hsinchu City (TW)

(21) Appl. No.: 18/527,433

(22) Filed: Dec. 4, 2023

(51) Int. Cl. H01L 21/3065; H01J 37/32; H01L 21/3213; H01L 21/67

(52) U.S. Cl. CPC H01L 21/3065; H01J 37/3244; H01L 21/32137; H01L 21/67069; H01J 2237/3341

(57) ABSTRACT

The present inventive concept discloses a method for fabrication of a semiconductor structure, and an apparatus for fabrication of the semiconductor structure according to the method. The method comprises: providing a semiconductor structure which includes a plurality of first layers and a plurality of second layers, wherein each of the first layers lies parallelly on each of the second layers and the first layer comprises a first material and the second layer comprises a second material; performing a first etching process by irradiating neutral beam in a first direction onto a surface of the semiconductor structure to form a plurality of fin structures with sidewall surfaces of the first material and the second material; and performing a second etching process onto the sidewall surfaces to remove the second layers and form a plurality of voids, wherein the second etching process has an etching selectivity between the first material and the second material.

### BACKGROUND OF THE INVENTION

### 1. Field of the Invention

The present disclosure generally relates to semiconductor processing, particularly, to the etching process of the semiconductor structures in two directions by combination of anisotropic etching and isotropic etching.

### 2. Description of the Related Art

Semiconductor devices comprise integrated circuits that are formed on semiconductor wafers by depositing several thin layers of various materials over a substrate, and patterning the thin layers to form the integrated circuits. One of the goals of the semiconductor industry is to continue shrinking the size and increasing the production efficiency of the integrated circuits including field-effect transistors (FETs).

However, the novel semiconductor structure with scaling down process generally faces the challenges of increased the complexity of processing and manufacturing. Fin FETs (finFETs) or GAAFETs are being researched and implemented.

Semiconductor manufacturing or fabrication often involves etching of the layers. When a plurality of layers made of at least two kinds of material are present on the surface of a substrate, it is crucial to control relative etching rates of one material, as compared to another material to selectively etch one of the layers precisely.

### SUMMARY OF THE INVENTION

In light of solving the foregoing problems of the prior art, the present inventive concept provides a method for fabrication of a semiconductor structure. The method comprises providing a semiconductor structure which includes a plurality of first layers and a plurality of second layers, wherein each of the first layers lies parallelly on each of the second layers and the first layer comprises a first material and the second layer comprises a second material; performing a first etching process by irradiating neutral beam in a first direction onto a surface of the semiconductor structure to form a plurality of fin structures with sidewall surfaces of the first material and the second material; and performing a second etching process onto the sidewall surfaces to remove the second layers and form a plurality of voids, wherein the second etching process has an etching selectivity between the first material and the second material.

According to an embodiment of the present inventive concept, the first material is silicon.

According to an embodiment of the present inventive concept, the second material comprises germanium.

According to an embodiment of the present inventive concept, the higher content of germanium in the second material, the better etching selectivity between the first material and the second material, wherein the content of germanium contained in the second material is in a range between more than 0% and 50%.

According to an embodiment of the present inventive concept, the second material is silicon germanium.

According to an embodiment of the present inventive concept, the first direction is substantially vertical to the surface of the semiconductor structure to form the fin structures, wherein the sidewall surfaces are substantially parallel to the first direction.

According to an embodiment of the present inventive concept, the second etching process is performed in a second direction to form the voids, wherein the second direction is substantially vertical to the first direction.

According to an embodiment of the present inventive concept, an acceleration energy of the neutral beam performed onto the surface of the semiconductor structure is controlled by a radio frequency electric field in a range between 400 kHz and 800 kHz.

According to an embodiment of the present inventive concept, the neutral beam is generated in a first composition of gas, wherein the first composition of gas comprises halogen.

According to an embodiment of the present inventive concept, the second etching process is performed by radical species.

According to an embodiment of the present inventive concept, the radical species provides an etching rate of the second layers that is at least 10 times greater than an etching rate of the first layers.

According to an embodiment of the present inventive concept, the etching rate of the second layers is controlled by varying a parameter value which is at least one selected from a group consisting of a content of germanium contained in the second material, a kind of the radical species, a flowing rate of the radical species, a time of exposure to the radical species, and a temperature of the fin structures.

According to an embodiment of the present inventive concept, the radical species comprise oxygen radical, nitrogen radical, fluorine radical, chlorine radical and hydrogen radical.

According to an embodiment of the present inventive concept, a second composition of gas in which the fluorine radical is generated is at least one selected from a group consisting of NF₃ and SF₆.

According to an embodiment of the present inventive concept, the first etching process is an anisotropic etching, and the second etching process is an isotropic etching.

The present inventive concept provides an apparatus for fabrication of a semiconductor structure according to the method of the present inventive concept. The apparatus comprises a first chamber for generating a plasma; a second chamber for receiving a neutral beam, and the semiconductor structure is positioned on a stage disposed on a side of the second chamber; an aperture disposed between the first chamber and the second chamber, wherein the neutral beam received in the second chamber is from the plasma generated in the first chamber flowing through the aperture; and a third chamber for generating radical species, wherein the third chamber is connected to a side of the second chamber between the aperture and the side disposed the stage.

According to an embodiment of the present inventive concept, the first chamber further comprises a gas inlet port for introducing a first composition of gas to generate the plasma, wherein the gas inlet port is provided on a side of the first chamber opposite to the aperture.

According to an embodiment of the present inventive concept, the first chamber further comprises an electrode, wherein the electrode is disposed upstream of the aperture.

According to an embodiment of the present inventive concept, the third chamber further comprises an orifice plate connected to the second chamber, wherein the radical species generated in the third chamber flows through the orifice plate to the second chamber.

According to an embodiment of the present inventive concept, the neutral beam from the aperture flows in a first direction, wherein the first direction is substantially vertical to the surface of the semiconductor structure.

According to an embodiment of the present inventive concept, the radical species from the third chamber flows in a second direction, wherein the second direction is substantially vertical to the first direction.

Compared to the conventional etching approach, the present inventive concept provides defect-free sidewall surfaces generated by the first etching process and then high etching selectivity between the first material and the second material is achieved by the second etching process. The present inventive concept provides a method enabling etching the semiconductor structures in two directions and forming roughness-free etched surfaces to fabricate the semiconductor structures more precisely, which makes miniaturization of the semiconductor devices possible.

### BRIEF DESCRIPTION OF THE DRAWINGS

FIG. 1 is a flowchart of an embodiment of the method of the present inventive concept;

FIG. 2 is a structural diagram showing the semiconductor structure before etching;

FIG. 3 is a structural diagram showing the semiconductor structure performed by the first etching process;

FIG. 4 is a structural diagram showing the semiconductor structure performed by the second etching process; and

FIG. 5 is a schematic diagram showing the apparatus for applying the method of the present inventive concept.

### DETAILED DESCRIPTION

The present inventive concept is described by the following specific embodiments. Those with ordinary skills in the arts can readily understand other advantages and functions of the present inventive concept after reading the disclosure of this specification. Any changes or adjustments made to their relative relationships, without modifying the substantial technical contents, are also to be construed as within the range implementable by the present inventive concept.

Moreover, the word “exemplary” or “embodiment” is used herein to mean serving as an example, instance, or illustration. Any aspect or design described herein as exemplary or an embodiment is not necessarily to be construed as preferred or advantageous over other aspects or designs. Rather, use of the word “exemplary” or “embodiment” is intended to present concepts and techniques in a concrete fashion.

As used in this application, the term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more,” unless specified otherwise or clear from context to be directed to a singular form.

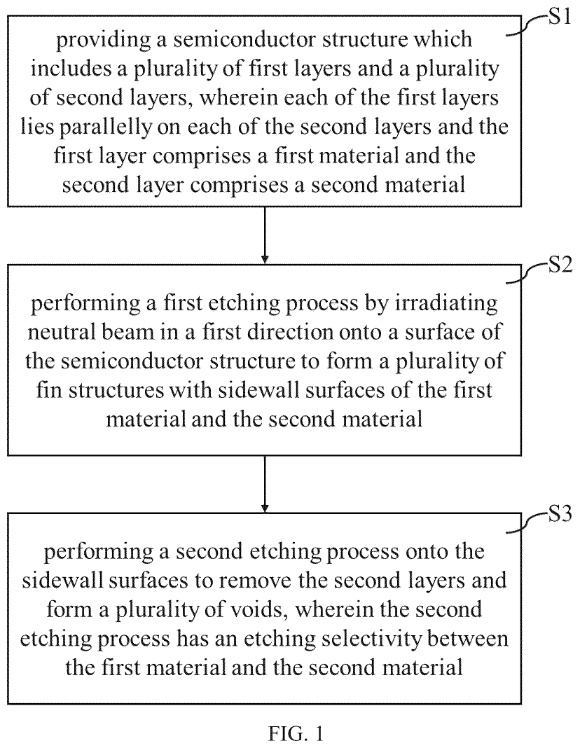

Please refer to FIG. 1 which is a flowchart of the method of the present inventive concept. In a first aspect, the present inventive concept provides a method for fabrication of a semiconductor structure.

The method of the present inventive concept comprises:
S1. providing a semiconductor structure which includes a plurality of first layers and a plurality of second layers, wherein each of the first layers lies parallelly on each of the second layers and the first layer comprises a first material and the second layer comprises a second material;
S2. performing a first etching process by irradiating neutral beam in a first direction onto a surface of the semiconductor structure to form a plurality of fin structures with sidewall surfaces of the first material and the second material; and
S3. performing a second etching process onto the sidewall surfaces to remove the second layers and form a plurality of voids, wherein the second etching process has an etching selectivity between the first material and the second material.

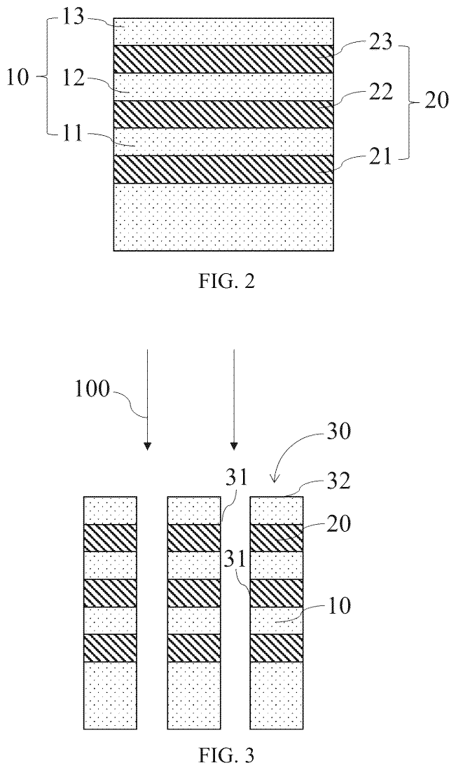

Please refer to FIG. 1 and FIG. 2. FIG. 2 is a structural diagram showing the semiconductor structure before etching. The semiconductor structure may include the plurality of first layers 10 interleaved with the plurality of second layers 20. As shown in FIG. 2, the first layer 12 may lie parallelly on the second layer 22, and the second layer 22 may lie parallelly on the first layer 11.

In an embodiment of the present inventive concept, the first layer 10 comprises a first material, wherein the first material may be silicon, Si.

In an embodiment of the present inventive concept, the second layer 20 comprises a second material, wherein the second material may comprise germanium, Ge.

In an embodiment of the present inventive concept, the second material may be, but not limited to, for example silicon germanium.

In an embodiment of the present inventive concept, the first layer 10 or the second layer 20 further comprise unavoidable substances, i.e. impurities. The unavoidable substances are present in the first layer 10 or the second layer 20 because of the limitation of manufacturing technology or cost. The content of impurities is limited to 0.1%.

In an embodiment of the present inventive concept, as shown in FIG. 2, the top surface of the semiconductor structure may be the first layer 13.

Please refer to FIG. 1 to FIG. 3. FIG. 3 is a structural diagram showing the semiconductor structure performed by the first etching process. In an embodiment of the present inventive concept, the first direction 100 may be substantially vertical to the surface 32 of the semiconductor structure to form the fin structures 30, wherein the sidewall surfaces 31 of the fin structures 30 may be substantially parallel to the first direction 100.

In an embodiment of the present inventive concept, the first etching process is performed onto the surface 32 of the first layer 13.

In an embodiment of the present inventive concept, an acceleration energy of the neutral beam performed onto the surface 32 of the semiconductor structure may be controlled by a radio frequency electric field in a range between 400 kHz and 800 kHz. Preferably, the acceleration energy of the neutral beam performed onto the surface 32 of the semiconductor structure controlled by the radio frequency electric field may be approximately 600 kHz.

In an embodiment of the present inventive concept, the neutral beam is generated in a first composition of gas, wherein the first composition of gas may comprise halogen.

In a preferred embodiment of the present inventive concept, the first composition of gas may comprise F₂, Cl₂, HBr, Br₂, HI and I₂, but not limited thereto.

In an embodiment of the present inventive concept, the first etching process may be an anisotropic etching.

According to the present inventive concept, the fin structures 30 formed by the first etching process with the neutral beam on the semiconductor structure may have the sidewall surfaces 31 with low roughness and low defect density. In an embodiment of the present inventive concept, the roughness of the sidewall surfaces 31 may be less than 1 N, and the defect density of that may be less than 10¹⁰/cm².

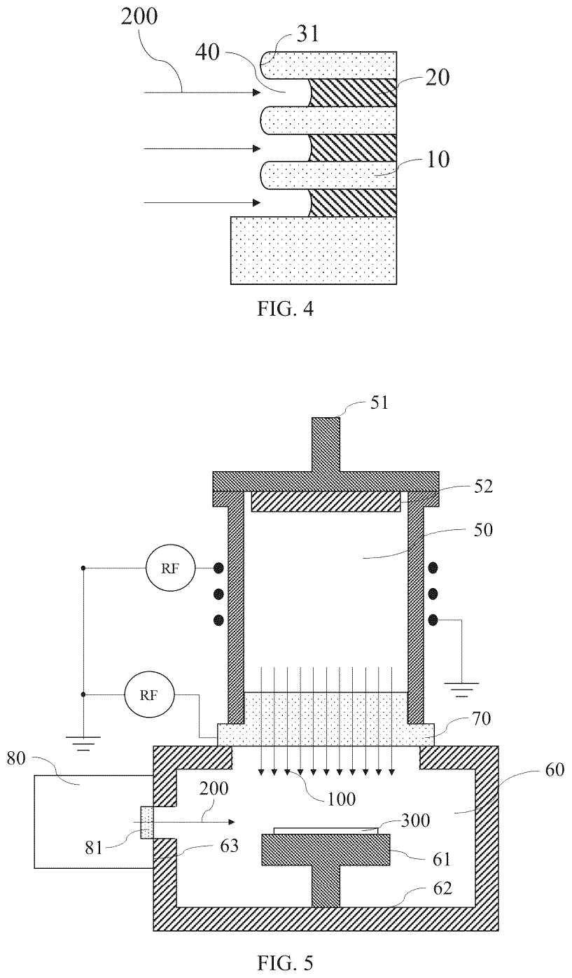

Please refer to FIG. 1 to FIG. 4. FIG. 4 is a structural diagram showing the semiconductor structure performed by the second etching process. In an embodiment of the present inventive concept, the second etching process is performed in a second direction 200 to form the voids 40.

In an embodiment of the present inventive concept, the second direction 200 may be substantially vertical to the first direction 100.

According to the present inventive concept, the second etching process has the etching selectivity between the first material and the second material, which enables the selective removal of the second material in the second layers 20. In other words, the better etching selectivity between the first material and the second material, the more difference of etching rate between the first layers 10 and the second layers 20.

In an embodiment of the present inventive concept, the second etching process may be performed by radical species.

In an embodiment of the present inventive concept, the radical species provides an etching rate of the second layers 20 that may be at least 10 times greater than an etching rate of the first layers 10. Preferably, the etching rate of the second layers 20 may be 10 times to 50 times greater than the etching rate of the first layers 10. More preferably, the etching rate of the second layers 20 may be 10 times to 30 times greater than the etching rate of the first layers 10.

According to the present inventive concept, the etching rate of the second layers 20 is controlled by modifying parameters, such as a content of germanium in the second material, the choice of the radical species, a flowing rate of the radical species, an exposure time of the structure to the radical species, and an exposure temperature of the fin structures.

In an embodiment of the present inventive concept, the etching rate of the second layers 20 is controlled by the content of germanium in the second material. According to the present inventive concept, the more germanium in the second material, the faster the second layers 20 may be etched.

According to the present inventive concept, high content of germanium in the second material may lead to a better etching selectivity between the first material and the second material,

In an embodiment of the present inventive concept, the content of germanium contained in the second material may be in a range between more than 0% and 50%. For instance, when the content of germanium in the second material is increased from 15% to 20%, the etching selectivity between the first material and the second material would enhance to approximately 3 times; when the content of germanium in the second material is increased from 15% to 25%, the etching selectivity between the first material and the second material would enhance to approximately 4 times; when the content of germanium in the second material is increased from 15% to 30%, the etching selectivity between the first material and the second material would enhance to approximately 4.1 times to 4.5 times.

In an embodiment of the present inventive concept, the second etching process is performed by radical species which may comprise oxygen radical, nitrogen radical, fluorine radical, chlorine radical and hydrogen radical, but not limited thereto.

In an embodiment of the present inventive concept, the etching rate of the second layers 20 may be controlled by the kind of the radical species. In a preferred embodiment of the present inventive concept, a desirable etching selectivity of the radical species between the first material and the second material may be provided by oxygen radicals, nitrogen radicals, fluorine radicals or chlorine radicals. More preferably, fluorine radicals may provide a better etching rate of the second layers 20, which has the excellent etching selectivity between the first material and the second material.

In an embodiment of the present inventive concept, a second composition of gas in which the fluorine radical is generated may be at least one selected from a group consisting of NF₃ and SF₆. For example, there is 70 sccm (Standard Cubic Centimeter per Minute) of NF₃ gas, SF₆ gas or the combination of NF₃ and SF₆ gas introduced to generate fluorine radical.

In an embodiment of the present inventive concept, the radical species may be generated from the second composition of gas by a plasma source applying high pressure.

In an embodiment of the present inventive concept, the etching rate of the second layers is controlled by the flowing rate of the radical species. In this embodiment, the flowing rate of the radical species may be influence by a discharge pressure and a microwave applied to a radical generator. For example, the flowing rate of the fluorine radical may be achieved by applying approximately 1 torr of the discharge pressure and 150 W, 2.45 GHz of microwave, to the radical generator.

In an embodiment of the present inventive concept, the etching rate of the second layers is controlled by the time of exposure to the radical species, wherein the time of exposure to the radical species may be in a range between 10 seconds and 60 seconds. Preferably, the time of exposure to the radical species may be in a range between 20 seconds and 40 seconds. More preferably, the time of exposure to the radical species may be approximately 30 seconds.

In an embodiment of the present inventive concept, the etching rate of the second layers is controlled by the temperature of the fin structures, wherein the temperature of the fin structures may be in a range between 100° C. and 200° C. Preferably, the temperature of the fin structures may be in a range between 100° C. and 150° C. More preferably, the temperature of the fin structures may be approximately 130° C.

According to the present inventive concept, the bonding energy between the radical species and the first material may be higher than that between the radical species and the second material. Therefore, the radical species prefer to react with the second material rather than the first material so that the second layers 20 may be selectively etched by the second etching process.

In an embodiment of the present inventive concept, the first material may be silicon in which the energy of Si—Si bond is about 2.31 eV. The second material may be silicon germanium in which the energy of Si—Ge bond is about 2.21 eV. In this embodiment, the radical species, such as fluorine radical, may prefer to react with silicon germanium rather than silicon and thereby produce gaseous compounds, for example, but not limited to Germanium tetrafluoride (GeF₄). The voids 40 are formed after the gaseous compounds are generated and dispersed.

In an embodiment of the present inventive concept, the second etching process may be an isotropic etching.

Compared to the conventional ion etching, the sidewall surfaces 31 of the present inventive concept performed by the neutral beam are smooth so that the radical species may be not easily to react with the first layers 10. According to the present inventive concept, both of the first etching process and the second etching process contribute to the high etching selectivity of the method of the present inventive concept.

In a second aspect, the present inventive concept provides an apparatus for fabrication of a semiconductor structure according to the method of the present inventive concept.

Please refer to FIG. 5 which is a schematic diagram showing the apparatus for applying the method of the present inventive concept. The apparatus may comprise a first chamber 50, a second chamber 60, an aperture 70 and a third chamber 80. The first chamber 50 is used for generating a plasma. The second chamber 60 is used for receiving a neutral beam, and the semiconductor structure 300 may be positioned on a stage 61 disposed on a side 62 of the second chamber 60. The aperture 70 may be disposed between the first chamber 50 and the second chamber 60, wherein the neutral beam received in the second chamber 60 is generated by the plasma from the first chamber 50 passing through the aperture 70. The third chamber 80 is used for generating radical species, wherein the third chamber 80 may be connected to a side 63 of the second chamber 60.

In an embodiment of the present inventive concept, the first chamber 50 may further comprise a gas inlet port 51 for introducing a first composition of gas to generate the plasma. Preferably, the gas inlet port 51 may be provided on a side of the first chamber 50 opposite to the aperture 70.

In an embodiment of the present inventive concept, the first chamber 50 may further comprise an electrode 52, wherein the electrode 52 may be disposed upstream of the aperture 70. Preferably, there is two electrodes disposed in the apparatus. One of the electrodes 52 is provided in the first chamber 50 and the other of the electrodes is the aperture 70. The plasma is passed through the aperture 70 by applying a voltage between the electrodes 52 and the aperture 70 to generate the neutral beam.

In a preferred embodiment of the present inventive concept, the electrode 52 is adjacent to the gas inlet port 51. Therefore, more plasma generated in the first composition of gas introduced from the gas inlet port 51 may be forced to pass through the aperture 70 by the voltage between the electrodes 52 and the aperture 70.

In an embodiment of the present inventive concept, the third chamber 80 may further comprise an orifice plate 81 disposed between the third chamber 80 and the second chamber 60, wherein the radical species generated in the third chamber 80 may flow through the orifice plate 81 to the second chamber 60.

In an embodiment of the present inventive concept, the radical species comprises oxygen radical, nitrogen radical, fluorine radical, chlorine radical and hydrogen radical, but not limited thereto. The second composition of gas may be introduced into the third chamber 80 for generating the radical species. Preferably, the second composition of gas, NF₃ or SF₆, may be introduced into the third chamber 80 for generating the fluorine radical.

In an embodiment of the present inventive concept, the third chamber 80 may further comprise a plasma source (not shown in FIG.), wherein the radical species are generated by the plasma source applying high pressure.

Please refer to FIG. 3 and FIG. 5. In an embodiment of the present inventive concept, the neutral beam from the aperture 70 flows in a first direction 100, wherein the first direction 100 may be substantially vertical to the surface 32 of the semiconductor structure 300.

In an embodiment of the present inventive concept, the radical species from the third chamber 80 flows in a second direction 200, wherein the second direction 200 may be substantially vertical to the first direction 100.

Compared to the conventional etching approach, the present inventive concept provides a method to fabricate a semiconductor structure with defect-free sidewall surfaces generated by the first etching process, and defect-free voids on the sidewalls resulted from the high etching selectivity between the first material and the second material achieved by the second etching process. The method of the present inventive concept enables etching the semiconductor structures in two directions and forming roughness-free etched surfaces to fabricate the semiconductor structures more precisely. The present inventive concept is believed to be a key enabler for the next-generation of semiconductor structures such as nanosheets, nanowires and GAA devices.

The foregoing descriptions of the detailed embodiments are only illustrated to disclose the features and functions of the present inventive concept and not restrictive of the scope of the present inventive concept. It should be understood to those in the art that all modifications and variations according to the spirit and principle in the disclosure of the present inventive concept should fall within the scope of the appended claims.

What is claimed is:

1. A method for fabrication of a semiconductor structure, which comprises:
providing a semiconductor structure which includes a plurality of first layers and a plurality of second layers, wherein each of the first layers lies parallelly on each of the second layers and the first layer comprises a first material and the second layer comprises a second material;
performing a first etching process by irradiating neutral beam in a first direction onto a surface of the semiconductor structure to form a plurality of fin structures with sidewall surfaces of the first material and the second material; and
performing a second etching process onto the sidewall surfaces to remove the second layers and form a plurality of voids, wherein the second etching process has an etching selectivity between the first material and the second material.

2. The method of claim 1, wherein the first material is silicon.

3. The method of claim 1, wherein the second material comprises germanium.

4. The method of claim 3, wherein the higher content of germanium in the second material, the better etching selectivity between the first material and the second material, wherein the content of germanium contained in the second material is in a range between more than 0% and 50%.

5. The method of claim 1, wherein the second material is silicon germanium.

6. The method of claim 1, wherein the first direction is substantially vertical to the surface of the semiconductor structure to form the fin structures, wherein the sidewall surfaces are substantially parallel to the first direction.

7. The method of claim 6, wherein the second etching process is performed in a second direction to form the voids, wherein the second direction is substantially vertical to the first direction.

8. The method of claim 1, wherein an acceleration energy of the neutral beam performed onto the surface of the semiconductor structure is controlled by a radio frequency electric field in a range between 400 kHz and 800 kHz.

9. The method of claim 1, wherein the neutral beam is generated in a first composition of gas, wherein the first composition of gas comprises halogen.

10. The method of claim 1, wherein the second etching process is performed by radical species.

11. The method of claim 10, wherein the radical species provides an etching rate of the second layers that is at least 10 times greater than an etching rate of the first layers.

12. The method of claim 11, wherein the etching rate of the second layers is controlled by varying a parameter value which is at least one selected from a group consisting of a content of germanium contained in the second material, a kind of the radical species, a flowing rate of the radical species, a time of exposure to the radical species, and a temperature of the fin structures.

13. The method of claim 10, wherein the radical species comprise oxygen radical, nitrogen radical, fluorine radical, chlorine radical and hydrogen radical.

14. The method of claim 13, wherein a second composition of gas in which the fluorine radical is generated is at least one selected from a group consisting of NF₃ and SF₆.

15. The method of claim 1, wherein the first etching process is an anisotropic etching, and the second etching process is an isotropic etching.

16. An apparatus for fabrication of a semiconductor structure according to the method of claim 1, the apparatus comprising:
a first chamber for generating a plasma;
a second chamber for receiving a neutral beam, and the semiconductor structure is positioned on a stage disposed on a side of the second chamber;
an aperture disposed between the first chamber and the second chamber, wherein the neutral beam received in the second chamber is from the plasma generated in the first chamber flowing through the aperture; and
a third chamber for generating radical species, wherein the third chamber is connected to a side of the second chamber between the aperture and the side disposed the stage.

17. The apparatus of claim 16, wherein the first chamber further comprises a gas inlet port for introducing a first composition of gas to generate the plasma, wherein the gas inlet port is provided on a side of the first chamber opposite to the aperture.

18. The apparatus of claim 16, wherein the first chamber further comprises an electrode, wherein the electrode is disposed upstream of the aperture.

19. The apparatus of claim 16, wherein the third chamber further comprises an orifice plate connected to the second chamber, wherein the radical species generated in the third chamber flows through the orifice plate to the second chamber.

20. The apparatus of claim 16, wherein the neutral beam from the aperture flows in a first direction, wherein the first direction is substantially vertical to the surface of the semiconductor structure.

21. The apparatus of claim 16, wherein the radical species from the third chamber flows in a second direction, wherein the second direction is substantially vertical to the first direction.
